(19) United States
(12) Patent Application Publication
(10) Pub. No.: US 2014/0020742 A1
(43) Pub. Date: Jan. 23, 2014

(54) PHOTOELECTRIC CONVERSION DEVICE AND METHOD FOR PRODUCING PHOTOELECTRIC CONVERSION DEVICE

(71) Applicant: SANYO Electric Co., Ltd., Osaka (JP)

(72) Inventors: Isao HASEGAWA, Hyogo (JP); Toshio ASAUMI, Osaka (JP); Hitoshi SAKATA, Osaka (JP); Toshiaki BABA, Hyogo (JP)

(73) Assignee: SANYO Electric Co., Ltd., Osaka (JP)

(21) Appl. No.: 14/036,675

(22) Filed: Sep. 25, 2013

Related U.S. Application Data
(63) Continuation of application No. PCT/JP2012/055338, filed on Mar. 2, 2012.

(30) Foreign Application Priority Data
Mar. 28, 2011 (JP) 2011-069364
Mar. 28, 2011 (JP) 2011-069577
Mar. 28, 2011 (JP) 2011-069670

(51) Int. Cl. H01L 31/0224

(52) U.S. Cl. CPC H01L 31/022441
USPC 136/255; 438/96; 136/256

(57) ABSTRACT

A photovoltaic device is provided with: an i-type amorphous layer formed over a region of at least a part of a back surface of a semiconductor substrate; and an i-type amorphous layer formed over a region of at least a part of a light-receiving surface of the semiconductor substrate. No electrode is provided on the light-receiving surface, and an electrode is provided on the back surface. An electrical resistance per unit area of the i-type amorphous layer is lower than an electrical resistance per unit area of the i-type amorphous layer.

### CROSS-REFERENCE TO RELATED APPLICATION

The present application is a continuation under 35 U.S.C. §120 of PCT/JP2012/055338, filed Mar. 2, 2012, which is incorporated herein. by reference and which claimed priority to Japanese Patent Application No. 2011-069670 filed Mar. 28, 2011, Japanese Patent Application No. 2011-069577 filed on Mar. 28, 201.1 and Japanese Patent Application No. 2011-069364 filed on Mar. 28, 2011. The present application likewise claims priority under 35 U.S.C. §119 to Japanese Patent Application No. 2011-069670 filed Mar. 28, 2011, Japanese Patent Application No. 2011-069577 filed on Mar. 28, 2011 and Japanese Patent Application No. 2011-069364 filed on Mar. 28, 2011, the entire contents of all three applications which. are all also incorporated herein by reference.

### TECHNICAL FIELD

The present invention relates to a back contact type photovoltaic device and to a method of producing the photovoltaic device.

### BACKGROUND ART

In order to improve power generation efficiency of a solar power generation system or the like, various types of photovoltaic devices are considered. Patent Document 1 discloses aback contact type photovoltaic device in which a p-type semiconductor region and an n-type semiconductor region are formed on a side opposite the light-receiving surface (back surface side) of a semiconductor substrate.

In the back contact type photovoltaic device, because no electrode is provided on the light-receiving surface side and the electrode is provided only on the back surface side, an effective light-receiving area can be increased and the power generation efficiency can be improved. In addition, because the connection between photovoltaic cells can be achieved solely on the back surface side, a wide-width wiring member can be used. Therefore, a voltage drop and power loss at the portion of the wiring member can be reduced.

### RELATED ART REFERENCES

### Patent Document

[Patent Document 1] JP 2009-200267 A

### DISCLOSURE OF INVENTION

### Technical Problem

In a back contact type photovoltaic device, the carriers generated by the photoelectric conversion in the semiconductor substrate must be efficiently collected at an electrode provided on the back surface.

In addition, in the back contact type photovoltaic device, the light must be efficiently introduced from the light-receiving surface to the semiconductor substrate which forms a carrier generation section, and absorption of light in the path from the light-receiving surface to the surface of the semiconductor substrate must be reduced as much as possible.

### Solution to Problem

According to one aspect of the present invention, there is provided a photovoltaic device comprising a semiconductor substrate, a first passivation layer comprising an amorphous semiconductor film and formed over a region of at least a part of a first surface of the semiconductor substrate, and a second passivation layer comprising an amorphous semiconductor film and formed over a region of at least a part of a second surface of the semiconductor substrate opposite the first surface, wherein no electrode is provided on the second surface side and an electrode is provided on the first surface side, and an electrical resistance per unit area of the first passivation layer is lower than an electrical resistance per unit area of the second passivation layer.

According to another aspect of the present invention, there is provided a photovoltaic device comprising a semiconductor substrate, a first passivation layer comprising an amorphous semiconductor film and formed over a region of at least a part of a first surface of the semiconductor substrate, and a second passivation layer comprising an amorphous semiconductor film and formed over a region of at least a part of a second surface of the semiconductor substrate opposite the first surface, wherein no electrode is provided on the second surface side and an electrode is provided on the first surface side, and an amount of absorption of light of the second passivation layer is lower than an amount of absorption of light of the first passivation layer.

According to another aspect of the present invention, there is provided a photovoltaic device comprising a semiconductor substrate, a first amorphous semiconductor layer of a first conductive type and formed over a region of at least a part of a first surface of the semiconductor substrate, and a second amorphous semiconductor layer of the first conductive type and formed over a region of at least a part of a second surface of the semiconductor substrate opposite the first surface, wherein an electrode is provided only on the second surface side, and the first amorphous semiconductor layer has a higher dopant concentration than the second amorphous semiconductor layer.

According to another aspect of the present invention, there is provided a photovoltaic device comprising a semiconductor substrate, a first amorphous semiconductor layer of a first conductive type and formed over a region of at least a part of a first surface of the semiconductor substrate, and a second amorphous semiconductor layer of the first conductive type and formed over a region of at least a part of a second surface of the semiconductor substrate opposite the first surface, wherein an electrode is provided only on the second surface side, and the first amorphous semiconductor layer has a lower hydrogen content than the second amorphous semiconductor layer.

According to another aspect of the present invention, there is provided a method of producing a photovoltaic device, comprising a first step in which a first passivation layer comprising an amorphous semiconductor film is formed over a region of at least a part of a first surface of a semiconductor substrate, a second step in which, after the first step, a second passivation layer comprising an amorphous semiconductor film is formed over a region of at least a part of a second surface of the semiconductor substrate opposite the first surface, and a third step in which, after the second step, an electrode is formed only on the first surface side, wherein the first passivation layer and the second passivation layer are formed such that an electrical resistance per unit area of the first passivation layer is lower than an electrical resistance per unit area of the second passivation layer.

According to another aspect of the present invention, there is provided a method of producing a photovoltaic device, comprising a first step in which a first passivation layer comprising an amorphous semiconductor film is formed over a region of at least a part of a first surface of a semiconductor substrate, a second step in which a second passivation layer comprising an amorphous semiconductor film is formed over a region of at least a part of a second surface of the semiconductor substrate opposite of the first surface, and a third step in which, after the second step, an electrode is formed only on the first surface side, wherein the first passivation layer and the second passivation layer are formed such that an amount of absorption of light of the second passivation layer is lower than an amount of absorption of light of the first passivation layer.

### Advantageous Effects of Invention

According to various aspects of the present invention, a photovoltaic device and a production method of the photovoltaic device can be provided in which the carriers generated by photoelectric conversion in the semiconductor substrate can be efficiently collected by electrodes provided on the back surface.

Further, according to various aspects of the present invention, a photovoltaic device and a producing method of the photovoltaic device can be provided in which light can be efficiently introduced from the light-receiving surface to the inside of the semiconductor substrate.

### BRIEF DESCRIPTION OF DRAWINGS

FIG. 1 is a back surface side plan view of a photovoltaic device according to a preferred embodiment of the present invention.

FIG. 2 is a cross sectional diagram of a photovoltaic device according to the preferred embodiment of the present invention.

FIG. 3 is a cross sectional diagram showing a production step of a photovoltaic device according to a first preferred embodiment of the present invention.

FIG. 4 is a cross sectional diagram showing a production step of a photovoltaic device according to the first preferred embodiment of the present invention.

FIG. 5 is a cross sectional diagram showing a production step of a photovoltaic device according to the first preferred embodiment of the present invention.

FIG. 6 is a diagram showing a production step of a photovoltaic device according to the first preferred embodiment of the present invention.

FIG. 7 is a diagram showing a production step of a photovoltaic device according to the first preferred embodiment of the present invention.

FIG. 8 is a schematic diagram for explaining plasma chemical vapor deposition in the first preferred embodiment of the present invention.

FIG. 9 is a cross sectional diagram showing a production step of a photovoltaic device according to a second preferred embodiment of the present invention.

### BEST MODE FOR CARRYING OUT THE INVENTION

### First Preferred Embodiment

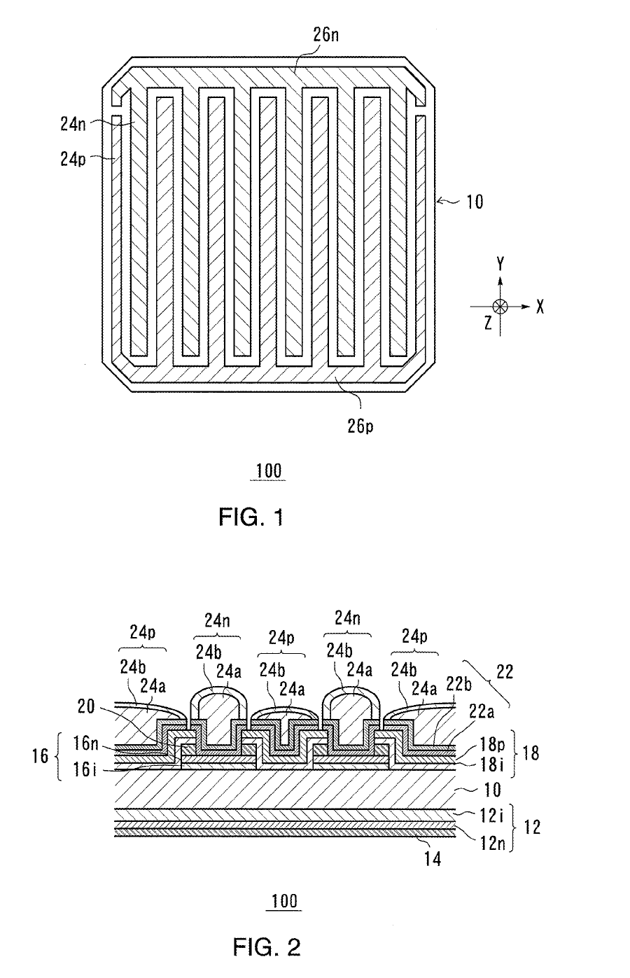

As shown in a back surface side plan view of FIG. 1 and a cross sectional diagram of FIG. 2, a photovoltaic device 100 according to a preferred embodiment of the present invention comprises a semiconductor substrate 10, an i-type amorphous layer 12i, an n-type amorphous layer 12n, a transparent protection layer 14, an i-type amorphous layer 16i, an n-type amorphous layer 16n, an i-type amorphous layer 18i, a p-type amorphous layer 18p, an insulating layer 20, an electrode layer 22, and electrode units 24 (24n and 24p) and 26 (26n and 26p).

FIG. 2 shows a part of a cross section along an X direction in FIG. 1. In addition, in FIG. 1, in order to clearly show regions of the electrode units 24 (24n and 24p) and 26 (26n and 26p), hatchings of different angles are applied.

The drawings in the present embodiment show the structures schematically, and the sizes and the ratios of the sizes may differ from those of the actual structures. In addition, the ratios of the sizes or the like may differ among the drawings. In the following description, a side of the photovoltaic device 100 on which the light is incident is described as a light-receiving surface and a side opposite the light-receiving surface is described as a back surface.

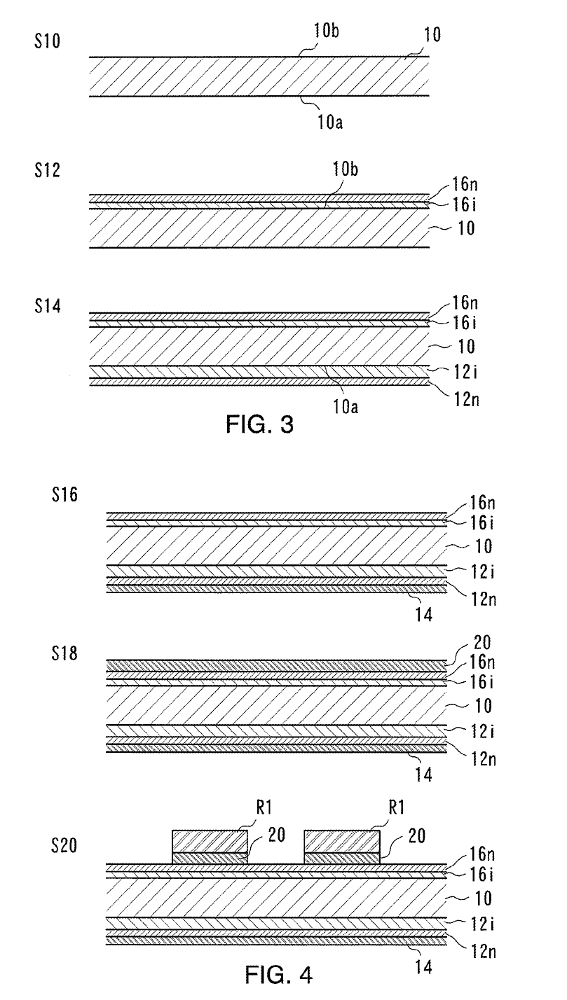

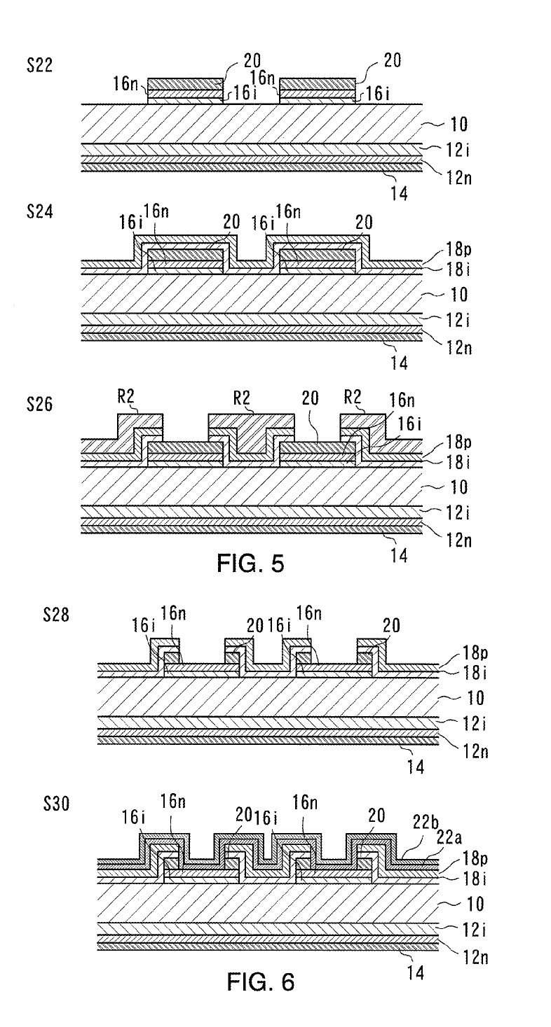

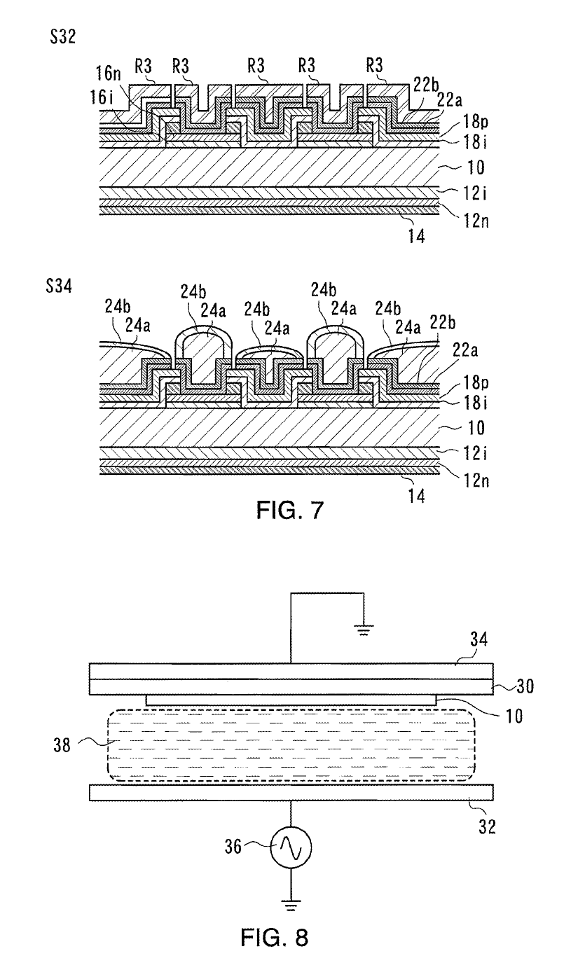

With reference to FIGS. 3-7, production steps of the photovoltaic device 100 and the structure of the photovoltaic device 100 will be described.

In step S10, a front surface and the back surface of the semiconductor substrate 10 are cleaned. The semiconductor substrate 10 may be a crystalline semiconductor substrate of an n-type conductivity or a p-type conductivity. As the semiconductor substrate 10, for example, a monocrystalline silicon substrate, a polycrystalline silicon substrate, a gallium arsenide substrate (GaAs), an indium phosphide substrate (InP), or the like may be employed. The semiconductor substrate 10 absorbs incident light and generates a carrier pair of an electron and a hole by means of photoelectric conversion. The semiconductor substrate 10 has a light-receiving surface 10a and a back surface 10b. In the following description, an example configuration is described in which an n-type silicon monocrystalline substrate is used as the semiconductor substrate 10.

The cleaning of the semiconductor substrate 10 can be executed using an etchant of hydrofluoric acid (etchant of HF) or an RCA cleaning solution. In addition, it is also preferable to form a texture structure in the light-receiving surface 10a of the semiconductor substrate 10 using an anisotropic etchant such as an etchant of potassium hydroxide (etchant of KOH). In this case, the semiconductor substrate 10 having a (100) plane is anisotropically etched using the etchant of KOH, to forma texture structure having a pyramid type, (111) plane.

In step S12, an i-type amorphous layer 16i and an n-type amorphous layer 16n are formed over the back surface 10b of the semiconductor substrate 10. The i-type amorphous layer 16i forms a part of the passivation layer covering at least a part of the back surface 10b of the semiconductor substrate 10.

The i-type amorphous layer 16i is a layer comprising an intrinsic amorphous semiconductor film. More specifically, the i-type amorphous layer 16i is formed from amorphous silicon containing hydrogen. The i-type amorphous layer 16i is formed to have a lower dopant concentration within the film than those of the n-type amorphous layers 12n and 16n and the p-type amorphous layer 18p.

A thickness of the i-type amorphous layer 16i is preferably set thin enough to inhibit absorption of light as much as possible and thick enough to achieve a sufficient passivation function for the back surface 10b of the semiconductor substrate 10. For example, the thickness of the i-type amorphous layer 16i is preferably greater than or equal to 0.1 nm and less than or equal to 25 nm.

The n-type amorphous layer 16n is a layer comprising an amorphous semiconductor film including a dopant of an n-type conductivity. Specifically, the n-type amorphous layer 16n is formed from amorphous silicon containing hydrogen. The n-type amorphous layer 16n is formed to have a higher dopant concentration within the film than the i-type amorphous layer 16i. For example, in the n-type amorphous layer 16n, the concentration of the dopant of the n-type is preferably greater than or equal to 1×10²¹ /cm³. A thickness of the n-type amorphous layer 16n is preferably set thin enough to inhibit absorption of light as much as possible and thick enough to achieve a sufficiently high open voltage for the photovoltaic device 100. For example, the thickness of the n-type amorphous layer 16n is preferably greater than or equal to 2 nm and less than or equal to 50 nm.

The i-type amorphous layer 16i and the n-type amorphous layer 16n can be formed through plasma chemical vapor deposition (PECVD) or the like. The i-type amorphous layer 12i can be formed by supplying a silicon-containing gas such as silane (SiH₄), which is turned into plasma by added RF high-frequency electric power to a parallel-plate electrode or the like, to a film formation surface of the semiconductor substrate which is heated. The n-type amorphous layer 16n can be formed by supplying a silicon-containing gas such as silane (SiH₄) with added phosphine (PH₃), which is turned into plasma by added RF high-frequency electric power to a parallel-plate electrode or the like, to a film formation surface of the semiconductor substrate 10 which is heated. In this process, the silicon-containing gas may be diluted by hydrogen (H₂), to change film characteristics of the i-type amorphous layer 16i and the n-type amorphous layer 16n which are formed according to the dilution percentage.

Specifically, as shown in FIG. 8, the i-type amorphous layer 16i can be formed by supplying a silicon-containing gas such as silane (SiH₄), which is turned into plasma by added RF high-frequency electric power to a parallel-plate electrode or the like, to a film formation surface of the semiconductor substrate 10 which is heated. The semiconductor substrate 10 is fixed on a substrate holder 30, and is placed on a ground electrode 34. The ground electrode 34 is placed to oppose a high-frequency electrode 32. A high-frequency power supply 36 is connected to the high-frequency electrode 32, and the ground electrode 34 is grounded. In this state, while the silicon-containing gas such as silane (SiH₄) is supplied, the high-frequency electric power is supplied from the high-frequency power supply 36 to the high-frequency electrode 32 so that plasma 38 of the material gas is generated. The material is supplied from the plasma 38 onto the surface of the semiconductor substrate 10 and a silicon thin film is formed.

In the present embodiment, the amorphous layer includes a microcrystalline semiconductor film. The microcrystalline semiconductor film is a film in which crystal grains are precipitated in the amorphous semiconductor. An average grain size of the crystal grains is, although not limited to the following, estimated to be approximately greater than or equal to 1 nm and less than or equal to 80 nm.

In step S14, the i-type amorphous layer 12i and the n-type amorphous layer 12n are formed over the light-receiving surface 10a of the semiconductor substrate 10. The i-type amorphous layer 12i forms a passivation layer which covers at least a part of the light-receiving surface 10a of the semiconductor substrate 10.

The i-type amorphous layer 12i is a layer comprising an intrinsic amorphous semiconductor film. More specifically, the i-type amorphous layer 12i is formed from amorphous silicon containing hydrogen. The i-type amorphous layer 12i is set to have a lower dopant concentration within the film than the n-type amorphous layers 12n and 16n and the p-type amorphous layer 18p.

The i-type amorphous layer 12i is preferably formed thin enough to inhibit absorption of light as much as possible and thick enough to achieve a sufficient passivation function for the light-receiving surface 10a of the semiconductor substrate 10. For example, the thickness of the i-type amorphous layer 12i is preferably greater than or equal to 0.2 nm and less than or equal to 50 nm.

The n-type amorphous layer 12n is a layer comprising an amorphous semiconductor film including a dopant of an n-type conductivity. More specifically, the n-type amorphous layer 12n is formed from amorphous silicon containing hydrogen. The n-type amorphous layer 12n is set to have a higher dopant concentration within the film than the i-type amorphous layer 12i. For example, the concentration of the n-type dopant in the n-type amorphous layer 12n is preferably greater than or equal to 1×10²¹ /cm³. A thickness of the n-type amorphous layer 12n is preferably set thin enough to inhibit absorption of light as much as possible and thick enough to allow movement of the carriers generated near the light-receiving surface of the photovoltaic device 100 to the electrode layer 22. For example, the thickness of the n-type amorphous layer 12n is preferably greater than or equal to 2 nm and less than or equal to 50 nm.

The i-type amorphous layer 12i and the n-type amorphous layer 12n can be formed through plasma chemical vapor deposition (PECVD) or the like. Specifically, similar to the i-type amorphous layer 16i and the n-type amorphous layer 16n, the i-type amorphous layer 12i can be formed by supplying a silicon-containing gas such as silane (SiH₄), which is turned into plasma by added RF high-frequency electric power to a parallel-plate electrode or the like, to a film formation surface of the semiconductor substrate 10 which is heated. The n-type amorphous layer 12n can be formed by supplying a silicon-containing gas such as silane (SiH₄) with added phosphine (PH₃), which is turned into plasma by added RF high-frequency electric power to a parallel-plate electrode or the like, to a film formation surface of the semiconductor substrate 10 which is heated. In this process, the silicon-containing gas can be diluted by hydrogen (H₂) so that the film characteristics of the i-type amorphous layer 12i and the n-type amorphous layer 12n which are formed can be changed according to the dilution percentage.

In step S16, the transparent protection layer 14 is formed over the n-type amorphous layer 12n. The transparent protection layer 14 has a function as an antireflection film and a function as a protection film for the light-receiving surface of the photovoltaic device 100. The transparent protection layer 14 may be conductive or may be insulating. The transparent protection layer 14 maybe formed, for example, with a transparent insulating material such as silicon oxide, silicon nitride, and silicon oxynitride, or a transparent conductive material such as tin oxide and indium tin oxide. A thickness of the transparent protection layer 14 is preferably set appropriately such that the antireflection characteristic to be achieved can be realized according to the index of refraction of the material or the like. The thickness of the transparent protection layer 14 is preferably set greater than or equal to 80 nm and less than or equal to 1 μm, for example.

The transparent protection layer 14 can be formed by sputtering using a target including the material to be applied, chemical vapor deposition (CVD) using gas containing the element of the material to be applied, or the like.

The transparent protection layer 14 is preferably made of a material and in a composition such that the transparent protection layer 14 is not etched in the subsequent steps. If the transparent protection layer 14 is etched in the subsequent steps, the transparent protection layer 14 may be again formed over the n-type amorphous layer 12n.

In step S18, the insulating layer 20 is formed over the n-type amorphous layer 16n. The insulating layer 20 is provided such that a surface of the n-type amorphous layer 16n on the back surface side and a surface of the i-type amorphous layer 18i on the light-receiving surface side do not contact each other. The insulating layer 20 may be transparent or non-transparent. The insulating layer 20 may be made of, for example, an insulating material such as silicon oxide, silicon nitride, silicon oxynitride, etc. It is particularly preferable that the insulating layer 20 is made of silicon nitride. In addition, the insulating layer 20 preferably contains hydrogen. A thickness of the insulating layer 20 is preferably greater than or equal to 80 nm and less than or equal to 1 μm, for example.

The insulating layer 20 may be formed through sputtering using a target including a material to be applied, chemical vapor deposition (CVD) using gas including the element of the material to be applied, or the like.

In step S20, the insulating layer 20 is etched. Specifically, etching is applied such that, of the insulating layer 20, a part over the region where the i-type amorphous layer 18i and the p-type amorphous layer 18p are formed is removed. For example, a resist R1 is applied, on a region where the insulating layer 20 is to be left, by screen printing or an inkjet method, to expose the region in which the insulating layer 20 is to be removed, and the insulating layer 20 in the region where the resist R1 is not applied is etched.

When the insulating layer 20 is made of silicon oxide, silicon nitride, or silicon oxynitride, for example, an etchant of hydrofluoric acid (etchant of HF) can be used as the etchant. After the etching, the resist R1 is removed.

In step S22, the i-type amorphous layer 16i and the n-type amorphous layer 16n are etched. Specifically, etching is applied such that, of the i-type amorphous layer 16i and the n-type amorphous layer 16n, a part over a region in which the i-type amorphous layer 18i and the p-type amorphous layer 18p are formed is removed.

Using the insulating layer 20 as a mask, etching is applied using an alkaline etchant on the i-type amorphous layer 16i and the n-type amorphous layer 16n exposed from the insulating layer 20. As the etchant, for example, an etchant containing sodium hydroxide (NaOH) may be used. With this process, of the back surface 10b of the semiconductor substrate 10, a region not covered with the insulating layer 20 is exposed.

In step S24, the i-type amorphous layer 18i and the p-type amorphous layer 18p are formed on the side of the back surface 10b of the semiconductor substrate 10. The i-type amorphous layer 18i forms at least a part of a passivation layer covering at least a part of the back surface 10b of the semiconductor substrate 10.

The i-type amorphous layer 18i is a layer comprising an intrinsic amorphous semiconductor film. Specifically, the i-type amorphous layer 18i is formed from amorphous silicon containing hydrogen. The i-type amorphous layer 18i is set to have a lower dopant concentration within the film than the n-type amorphous layers 12n and 16n and the p-type amorphous layer 18p.

A thickness of the i-type amorphous layer 18i is preferably set thin enough to inhibit absorption of light as much as possible and thick enough to achieve a sufficient passivation function for the back surface 10b of the semiconductor substrate 10. For example, the thickness of the i-type amorphous layer 18i is preferably greater than or equal to 0.1 nm and less than or equal to 25 nm.

Here, preferably, at least one of the thicknesses of the i-type amorphous layer 16i and the i-type amorphous layer 18i is thinner than the thickness of the i-type amorphous layer 12i. The thicknesses of the i-type amorphous layer 12i, the i-type amorphous layer 16i, and the i-type amorphous layer 18i may be changed, for example, by adjusting the film formation time during the film formation, a substrate temperature during the film formation, concentration of the silicon-containing gas in the material gas and the hydrogen dilution percentage, the high-frequency electric power supplied to the plasma, or the like. In general, if the other conditions are identical, when the film formation time during the film formation is prolonged, the concentration of the silicon-containing gas in the material gas is increased, the hydrogen dilution percentage in the material gas is reduced, or the high-frequency electric power to be supplied to the plasma is increased, the thicknesses of the i-type amorphous layer 12i, the i-type amorphous layer 16i, and the i-type amorphous layer 18i tend to be thickened.

The thicknesses of the i-type amorphous layer 12i, the i-type amorphous layer 16i, and the i-type amorphous layer 18i can be measured through transmission cross-section electron microscope observation (TEM) or the like. When there is a distribution in the thickness, an average thickness may be used as an index for comparison.

In addition, preferably, at least one of hydrogen contents in the film of the i-type amorphous layer 16i and the i-type amorphous layer 18i is lower than a hydrogen content of the i-type amorphous layer 12i. The hydrogen contents of the i-type amorphous layer 12i, the i-type amorphous layer 16i, and the i-type amorphous layer 18i can be changed, for example, by adjusting the concentration of the silicon-containing gas in the material gas, the hydrogen dilution percentage, the substrate temperature during the film formation, the high-frequency electric power supplied to the plasma, or the like. In general, if the other conditions are identical, when the substrate temperature during the film formation is increased, the concentration of the silicon-containing gas in the material gas is increased, the hydrogen dilution percentage in the material gas is reduced, or the high-frequency electric power supplied to the plasma is increased, the hydrogen contents of the i-type amorphous layer 12i, the i-type amorphous layer 16i, and the i-type amorphous layer 18i tend to be reduced.

The hydrogen contents of the i-type amorphous layer 12i, the i-type amorphous layer 16i, and the i-type amorphous layer 18i may be measured through elastic recoil detection analysis (ERDA), Fourier transform infrared spectroscopy (FT-IR), or the like. When there is a distribution in the hydrogen content in the film, a spatial average may be used as an index for comparison.

The p-type amorphous layer 18p is a layer comprising an amorphous semiconductor film including a dopant of p-type conductivity. Specifically, the p-type amorphous layer 18p is formed from amorphous silicon containing hydrogen. The p-type amorphous layer 18p is set to have a higher dopant concentration within the film than the i-type amorphous layer 18i. For example, a concentration of the p-type dopant in the p-type amorphous layer 18p is preferably set to be greater than or equal to 1×10²¹ /cm³.

A thickness of the p-type amorphous layer 18p is preferably set thin enough to inhibit absorption of light as much as possible and thick enough to achieve a sufficiently high open voltage for the photovoltaic device 100. For example, the thickness of the p-type amorphous layer 18p is preferably greater than or equal to 2 nm and less than or equal to 50 nm.

The i-type amorphous layer 18i and the p-type amorphous layer 18p can be formed through plasma chemical vapor deposition (PECVD) or the like. More specifically, the i-type amorphous layer 18i can be formed by supplying a silicon-containing gas such as silane (SiH₄), which is turned into plasma by added RF high-frequency electric power to a parallel-plate electrode or the like, to a film formation surface of the semiconductor substrate 10 which is heated. The p-type amorphous layer 18p can be formed by supplying a silicon-containig gas such as silane (SiH₄) with added diborane (B₂H₆), which is turned into plasma by added RF high-frequency electric power to a parallel-plate electrode or the like, to a film formation surface of the semiconductor substrate 10 which is heated. In this case, by diluting the silicon-containing gas with hydrogen (H₂), it is possible to change the film characteristics of the i-type amorphous layer 18i and the p-type amorphous layer 18p which are formed, according to the dilution percentage.

In step S26, a part of the i-type amorphous layer 18i and the p-type amorphous layer 18p covering the insulating layer 20 is removed.

Specifically, a resist R2 is applied, on a region of the i-type amorphous layer 18i and the p-type amorphous layer 18p to be left, through screen printing or an inkjet method, to expose the region where the i-type amorphous layer 18i and the p-type amorphous layer 18p are to be removed, and the i-type amorphous layer 18i and the p-type amorphous layer 18p are etched using the resist R2 as a mask. For the etching, an alkaline etchant may be used. For example, an etchant including sodium hydroxide (NaOH) may be used. After the etching, the resist R2 is removed.

Alternatively, the i-type amorphous layer 18i and the p-type amorphous layer 18p may be etched by applying an etching paste which has a paste-like shape or an etching ink having the viscosity adjusted on a region where the i-type amorphous layer 18i and the p-type amorphous layer 18p are to be removed. The etching paste and the etching ink can be applied in a predetermined pattern through screen printing or an inkjet method.

In step S28, the insulating layer 20 is etched. More specifically, using, as a mask, the i-type amorphous layer 18i and the p-type amorphous layer 18p having a part removed in step S26, the exposed part of the insulating layer 20 is etched and removed using an etchant. Here, there is used an etchant having a higher etching speed with respect to the insulating layer 20 than the etching speed with respect to the p-type amorphous layer 18p. For example, for the etchant, an etchant of hydrofluoric acid (HF) or the like may be used. With this process, only the insulating layer 20 exposed from the i-type amorphous layer 18i and the p-type amorphous layer 18p is selectively etched, and the n-type amorphous layer 16n is exposed in this region.

In step S30, the electrode layer 22 is formed over the n-type amorphous layer 16n and the p-type amorphous layer 18p. The electrode layer 22 forms a seed layer for forming the electrode unit 24. The electrode layer 22 preferably has a layered structure of a transparent conductive film 22a and a conductive layer 22b including a metal. The transparent conductive film 22a may be ITO, SnO₂, TiO₂, ZnO, or the like. The conductive layer 22b may be a metal such as copper (Cu), or an alloy thereof. The transparent conductive film 22a and the conductive layer 22b can be formed through a thin film formation method such as plasma chemical vapor deposition (PECVD) or sputtering.

In step S32, the electrode 22 is partitioned. Of the region in which the electrode layer 22 is formed, a part of the region formed over the insulating layer 20 is removed, to partition the layer into an electrode layer 22 electrically connected to the n-type amorphous layer 16n and an electrode layer 22 electrically connected to the p-type amorphous layer 18p. The partitioning of the electrode layer 22 can be achieved by a patterning technique using a resist R3. For the patterning, etching using ferric chloride (FeCl₃) and hydrochloric acid (HCl) may be applied. After the electrode layer 22 is partitioned, the resist R3 is removed.

In step S34, the electrode unit 24 is formed over the region where the electrode layer 22 is left. The electrode unit 24 can be formed by forming a metal layer through electroplating. The electrode unit 24 can be formed, for example, by sequentially layering an electrode unit 24a made of copper (Cu) and an electrode unit 24b made of tin (Sn). The electrode unit 24 is not limited to such a configuration, and may be made of other metals such as gold, silver, or the like, other conductive materials, or a combination thereof. By applying the electroplating while applying a potential on the electrode layer 22, the electrode unit 24 is formed only over the region where the electrode layer 22 is left.

With the partitioning process in step S32, the electrode unit 24n electrically connected to the n-type amorphous layer and the electrode unit 24p electrically connected to the p-type amorphous layer as shown in FIG. 1 are formed. The electrode unit 24n and the electrode unit 24p form finger electrodes. The photovoltaic device 100 is configured such that the electrode unit 24n and the electrode unit 24p forming the finger electrodes extend in the y direction and interdigitate each other in a comb-like shape. In addition, an electrode unit 26n connecting a plurality of the electrode units 24n and an electrode unit 26p connecting a plurality of the electrode units 24p are provided. These electrode units 26n and 26p become bus bar electrodes.

The photovoltaic device 100 in the present embodiment can be formed in a manner described above. In the present embodiment, when the photovoltaic device 100 is formed, the i-type amorphous layer 16i of the back surface is formed before the i-type amorphous layer 12i of the light-receiving surface. As shown in FIG. 8, in the plasma chemical vapor deposition or the like, a surface opposite the film formation surface may contact the substrate holder 30 or the like during the film formation, possibly resulting in adhesion of impurity or the like or contamination due to formation of an oxide film caused by heating during the film formation. In the present embodiment, the i-type amorphous layer 16i is formed prior to the i-type amorphous layer 12i, so as to prevent the contamination of the interface between the i-type amorphous layer 16i and the semiconductor substrate 10 and the interface between the i-type amorphous layer 18i and the semiconductor substrate 10 during the film formation of the i-type amorphous layer 12i, and to reduce a contact resistance between the semiconductor substrate 10 and the i-type amorphous layer 16i and between the semiconductor substrate 10 and the i-type amorphous layer 18i.

In addition, the thicknesses of the i-type amorphous layer 16i and the i-type amorphous layer 18i are set to be thinner than that of the i-type amorphous layer 12i, so that electrical resistances per unit area of the i-type amorphous layer 16i and the i-type amorphous layer 18i can be set lower than that of the i-type amorphous layer 12i. With such a configuration, the resistances in the thickness direction of the i-type amorphous layer 16i and the i-type amorphous layer 18i can be reduced.

Because the resistivity tends to be reduced when the hydrogen content is reduced, the hydrogen contents in the film of the i-type amorphous layer 16i and the i-type amorphous layer 18i are set lower than that of the i-type amorphous layer 12i so that the electrical resistances per unit area of the i-type amorphous layer 16i and the i-type amorphous layer 18i can be set lower than that of the i-type amorphous layer 12i. With such a configuration, the resistances in the thickness direction of the i-type amorphous layer 16i and the i-type amorphous layer 18i can be reduced.

In the back contact type photovoltaic device, the i-type amorphous layer 16i and the i-type amorphous layer 18i on the back surface side become paths of the carriers, and the i-type amorphous layer 12i does not become a path of the carriers. Therefore, by reducing the resistances in the thickness direction of the i-type amorphous layer 16i and the i-type amorphous layer 18i, a collection efficiency of the carriers can be improved. On the other hand, the characteristic of the i-type amorphous layer 12i does not need to be changed from those of the related art, and the light absorption or the like on the light-receiving surface side is not changed. Therefore, the power generation efficiency of the photovoltaic device can be improved.

### Second Preferred Embodiment

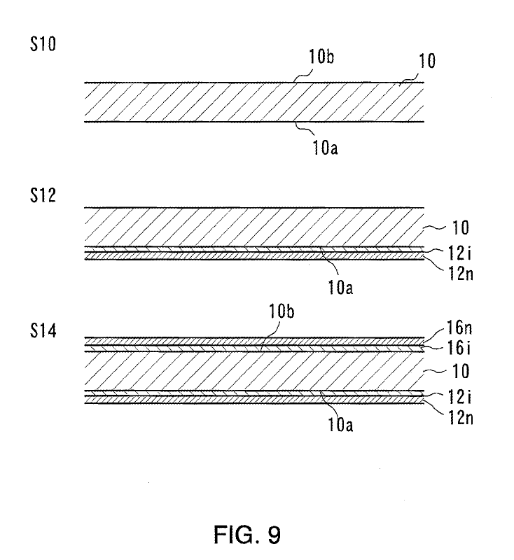

In the first preferred embodiment, the i-type amorphous layer 16i and the n-type amorphous layer 16n are formed before the i-type amorphous layer 12i and the n-type amorphous layer 12n. Alternatively, these layers may be formed in reverse order. More specifically, as shown in FIG. 9, a configuration may be employed in which, instep S12, the i-type amorphous layer 12i and the n-type amorphous layer 12n are formed, and, in step S14, the i-type amorphous layer 16i and the n-type amorphous layer 16n are formed. Here, the structure and the production method for which no particular explanation is given are similar to those of the first preferred embodiment.

In this process, the i-type amorphous layer 12i is preferably formed thin enough to inhibit absorption of light as much as possible and thick enough to achieve a sufficient passivation function for the light-receiving surface 10a of the semiconductor substrate 10. For example, the thickness of the i-type amorphous layer 12i is preferably greater than or equal to 0.1 nm and less than or equal to 25 nm.

Similarly, a thickness of the i-type amorphous layer 16i is preferably set thin enough to inhibit absorption of light as much as possible and thick enough to achieve a sufficient passivation function for the back surface 10b of the semiconductor substrate 10. For example, the thickness of the i-type amorphous layer 16i is greater than or equal to 0.2 nm and less than or equal to 50 nm.

Here, the thickness of the i-type amorphous layer 12i is preferably set thinner than the thicknesses of the i-type amorphous layer 16i and the i-type amorphous layer 18i.

In addition, the hydrogen content of the i-type amorphous layer 12i is preferably set higher than the hydrogen contents in the film of the i-type amorphous layer 16i and the i-type amorphous layer 18i.

The photovoltaic device 100 of the present embodiment can be formed in a manner described above. In the present embodiment, when the photovoltaic device 100 is formed, the i-type amorphous layer 12i on the light-receiving surface is formed before the i-type amorphous layer 16i of the back surface. In the present embodiment, by forming the i-type amorphous layer 12i before the i-type amorphous layer 16i, it is possible to prevent contamination of the interface between the i-type amorphous layer 12i and the semiconductor substrate 10 when the i-type amorphous layer 16i and the i-type amorphous layer 18i are formed. A region near the interface between the semiconductor substrate 10 and the i-type amorphous layer 12i is a region where the amount of generation of the carriers is the greatest, and, therefore, because the contamination at the interface between the semiconductor substrate 10 and the i-type amorphous layer 12i can be reduced, recombination of the carriers can be inhibited and the photovoltaic efficiency can be improved.

In addition, by setting the thickness of the i-type amorphous layer 12i to be thinner than those of the i-type amorphous layer 16i and the i-type amorphous layer 18i, the amount of absorption of light at the i-type amorphous layer 12i can be set to be lower than those of the i-type amorphous layer 16i and the i-type amorphous layer 18i. With such a configuration, the amount of light reaching from the light-receiving surface 10a to the inside of the semiconductor substrate 10 can be increased, and the photovoltaic efficiency can be improved.

Because the absorption of light tends to reduce with an increase in the hydrogen content, the hydrogen content in the film of the i-type amorphous layer 12i may be set higher than those of the i-type amorphous layer 16i and the i-type amorphous layer 18i so that the amount of absorption of light in the i-type amorphous layer 12i is smaller than those of the i-type amorphous layer 16i and the i-type amorphous layer 18i. With such a configuration, the amount of light reaching from the light-receiving surface 10a to the inside of the semiconductor substrate 10 can be increased and the photovoltaic efficiency can be improved.

### Third Preferred Embodiment

In a third preferred embodiment of the present invention, doping concentrations of the n-type amorphous layer 16n and the n-type amorphous layer 12n are adjusted. Structures and a production method for which no particular description is given are similar to those of the first or second preferred embodiment.

In the present embodiment, the doping concentration of the n-type amorphous layer 16n is preferably set higher than the doping concentration of the n-type amorphous layer 12n. The doping concentrations of the n-type amorphous layer 12n and the n-type amorphous layer 16n can be controlled, for example, by adjusting a mixture ratio of dopant-containing gas with respect to the silicon-containing gas in the material gas.

The doping concentrations of the n-type amorphous layer 16n and the n-type amorphous layer 12n can be measured through secondary ion mass spectrometry (SIMS) or the like. When there is a distribution in the doping concentration in the film, an average value over space (for example, in the depth direction or the like) may be used as an index for comparison.

The hydrogen content of the n-type amorphous layer 16n is preferably set lower than the hydrogen content of the n-type amorphous layer 12n. The hydrogen contents of the n-type amorphous layer 12n and the n-type amorphous layer 16n can be changed, for example, by adjusting the concentration of the silicon-containing gas in the material gas, the hydrogen dilution percentage, the substrate temperature during the film formation, the high-frequency electric power supplied to the plasma, or the like. In general, if the other conditions are identical, when the substrate temperature during the film formation is reduced, the concentration of the silicon-containing gas in the material gas is reduced, the hydrogen dilution percentage in the material gas is increased, or the high-frequency electric power supplied to plasma is reduced, the hydrogen contents of the n-type amorphous layer 12n and the n-type amorphous layer 16n tend to be increased.

The hydrogen contents of the n-type amorphous layer 16n and the n-type amorphous layer 12n can be measured using elastic recoil detection analysis (ERDA), Fourier transform infrared spectroscopy (FT-IR), or the like. When there is a distribution in the hydrogen content in the film, a spatial average value may be used as an index for comparison.

The photovoltaic device 100 in the present embodiment can be formed in a manner described above. When the doping concentration of the n-type amorphous layer 16n is set higher than the doping concentration of the n-type amorphous layer 12n, if the thickness is the same, the resistance value in the thickness direction of the n-type amorphous layer 16n can be set lower than the resistance value in the thickness direction of the n-type amorphous layer 12n. In the back contact type photovoltaic device, the n-type amorphous layer 16n on the back surface side becomes the path for the carriers, and the n-type amorphous layer 12n on the light-receiving surface side does not become a path for the carriers. Therefore, by reducing the resistance in the thickness direction of the n-type amorphous layer 16n, the power generation efficiency can be improved.

In addition, with the increase in the doping concentration, the amount of absorption of light is also increased. Therefore, by setting the doping concentration of the n-type amorphous layer 12n to be lower than the doping concentration of the n-type amorphous layer 16n, the absorption loss of light by the n-type amorphous layer 12n on the light-receiving surface side can also be reduced.

Moreover, when the hydrogen content of the n-type amorphous layer 16n is set to be lower than the hydrogen content of the n-type amorphous layer 12n, if the thickness is the same, the resistance value in the thickness direction of the n-type amorphous layer 16n can be set to be smaller than the resistance value in the thickness direction of the n-type amorphous layer 12n. With such a configuration, the power generation efficiency of the photovoltaic device 100 can be improved.

With the increase in the hydrogen content, the bandgap of the n-type amorphous layer is increased and the light absorption is reduced. By setting the hydrogen content of the n-type amorphous layer 12n to be higher than the hydrogen content of the n-type amorphous layer 16n, the absorption loss of light by the n-type amorphous layer 12n on the light-receiving surface side can be reduced.

In the above description, the polarities of the dopants for the semiconductor substrate 10, the n-type amorphous layer 12n, the n-type amorphous layer 16n, and the p-type amorphous layer 18p maybe suitably exchanged. For example, the polarities of the n-type amorphous layer 16n and the p-type amorphous layer 18p may be set to p-type and n-type, respectively, or the polarities of the semiconductor substrate 10 and the n-type amorphous layer 12n may be set to n-type.

### EXPLANATION OF REFERENCE NUMERALS

10 SEMICONDUCTOR SUBSTRATE; 10a LIGHT-RECEIVING SURFACE; 10b BACK

SURFACE; 12i i-TYPE AMORPHOUS LAYER; 12n n-TYPE AMORPHOUS LAYER; 14 TRANSPARENT PROTECTION LAYER; 16i i-TYPE AMORPHOUS LAYER; 16n n-TYPE AMORPHOUS LAYER; 18i i-TYPE AMORPHOUS LAYER; 18p p-TYPE AMORPHOUS LAYER; 20 INSULATING LAYER; 22 ELECTRODE LAYER; 22a TRANSPARENT CONDUCTIVE FILM; 22b CONDUCTIVE LAYER; 24 ELECTRODE UNIT; 24a ELECTRODE UNIT; 24b ELECTRODE UNIT; 24n FINGER ELECTRODE UNIT; 24p FINGER ELECTRODE UNIT; 26n BUS BAR ELECTRODE UNIT; 26p BUS BAR ELECTRODE UNIT; 30 SUBSTRATE HOLDER; 32 HIGH-FREQUENCY ELECTRODE; 34 GROUND ELECTRODE; 36 HIGH-FREQUENCY POWER SUPPLY; 38 PLASMA; 100 PHOTOVOLTAIC DEVICE

1. A photovoltaic device comprising:
a semiconductor substrate;
a first passivation layer comprising an amorphous semiconductor film and formed over a region of at least a part of a first surface of the semiconductor substrate; and
a second passivation layer comprising an amorphous semiconductor film and formed over a region of at least a part of a second surface of the semiconductor substrate opposite the first surface, wherein
no electrode is provided on the second surface side and an electrode is provided on the first surface side, and
an electrical resistance per unit area of the first passivation layer is lower than an electrical resistance per unit area of the second passivation layer.

2. The photovoltaic device according to claim 1, wherein a thickness of the first passivation layer is thinner than a thickness of the second passivation layer.

3. The photovoltaic device according to claim 1, wherein
a hydrogen content of the first passivation layer is lower than a hydrogen content of the second passivation layer.

4. A photovoltaic device comprising:
a semiconductor substrate;
a first passivation layer comprising an amorphous semiconductor film and formed over a region of at least a part of a first surface of the semiconductor substrate; and
a second passivation layer comprising an amorphous semiconductor film and formed over a region of at least a part of a second surface of the semiconductor substrate opposite the first surface, wherein
no electrode is provided on the second surface side and an electrode is provided on the first surface side, and
an amount of absorption of light of the second passivation layer is lower than an amount of absorption of light of the first passivation layer.

5. The photovoltaic device according to claim 4, wherein
a thickness of the second passivation layer is thinner than a thickness of the first passivation layer.

6. The photovoltaic device according to claim 4, wherein
a hydrogen content of the second passivation layer is higher than a hydrogen content of the first passivation layer.

7. A photovoltaic device comprising:
a semiconductor substrate;
a first amorphous semiconductor layer of a first conductive type and formed over a region of at least a part of a first surface of the semiconductor substrate; and
a second amorphous semiconductor layer of the first conductive type and formed over a region of at least a part of a second surface of the semiconductor substrate opposite the first surface, wherein
an electrode is provided only on the second surface side, and
the first amorphous semiconductor layer has a higher dopant concentration than the second amorphous semiconductor layer.

8. A photovoltaic device comprising:
a semiconductor substrate;
a first amorphous semiconductor layer of a first conductive type and formed over a region of at least a part of a first surface of the semiconductor substrate; and
a second amorphous semiconductor layer of the first conductive type and formed over a region of at least a part of a second surface of the semiconductor substrate opposite the first surface, wherein
an electrode is provided only on the second surface side, and
the first amorphous semiconductor layer has a lower hydrogen content than the second amorphous semiconductor layer.

9. The photovoltaic device according to claim 7, wherein
the first amorphous semiconductor layer and the second amorphous semiconductor layer are n-type amorphous silicon layers.

10. The photovoltaic device according to claim 8, wherein
the first amorphous semiconductor layer and the second amorphous semiconductor layer are n-type amorphous silicon layers.

11. The photovoltaic device according to claim 1, further comprising:
an amorphous silicon layer of a first conductive type and formed over a partial region of the first passivation layer; and
an amorphous silicon layer of a conductive type opposite the first conductive type and formed over a region of at least a part of the first passivation layer outside of the partial region.

12. A method of producing a photovoltaic device, comprising:
a first step in which a first passivation layer comprising an amorphous semiconductor film is formed over a region of at least a part of a first surface of a semiconductor substrate;
a second step in which, after the first step, a second passivation layer comprising an amorphous semiconductor film is formed over a region of at least a part of a second surface of the semiconductor substrate opposite the first surface; and
a third step in which, after the second step, an electrode is formed only on the first surface side, wherein
the first passivation layer and the second passivation layer are formed such that an electrical resistance per unit area of the first passivation layer is lower than an electrical resistance per unit area of the second passivation layer.

13. The method of producing the photovoltaic device according to claim 12, wherein
the first passivation layer and the second passivation layer are formed such that a thickness of the first passivation layer is thinner than a thickness of the second passivation layer.

14. The method of producing the photovoltaic device according to claim 12, wherein
the first passivation layer and the second passivation layer are formed such that a hydrogen content of the first passivation layer is lower than a hydrogen content of the second passivation layer.

15. A method of producing a photovoltaic device, comprising:
a first step in which a first passivation layer comprising an amorphous semiconductor film is formed over a region of at least a part of a first surface of a semiconductor substrate;
a second strep in which a second passivation layer comprising an amorphous semiconductor film is formed over a region of at least a part of a second surface of the semiconductor substrate opposite the first surface; and
a third step in which, after the second step, an electrode is formed only on the first surface side, wherein
the first passivation layer and the second passivation layer are formed such that an amount of absorption of light of the second passivation layer is lower than an amount of absorption of light of the first passivation layer.

16. The method of producing the photovoltaic device according to claim 15, wherein
the first passivation layer and the second passivation layer are formed such that a thickness of the second passivation layer is thinner than a thickness of the first passivation layer.

17. The method of producing the photovoltaic device according to claim 15, wherein
the first passivation layer and the second passivation layer are formed such that a hydrogen content of the second passivation layer is higher than a hydrogen content of the first passivation layer.

18. The method of producing the photovoltaic device according to claim 12, further comprising:
a step in which an amorphous silicon layer of a first conductive type is formed over a partial region of the first passivation layer; and
a step in which an amorphous silicon layer of a conductive type opposite the first conductive type is formed over a region of at least a part of the first passivation layer outside of the partial region.
